(19) United States
(12) Patent Application Publication
(10) Pub. No.: US 2019/0109237 A1
(43) Pub. Date: Apr. 11, 2019

(54) THIN FILM TRANSISTOR AND METHOD MANUFACTURING FOR SAME

(71) Applicant: SHENZHEN CHINA STAR OPTOELECTRONICS SEMICONDUCTOR DISPLAY TECHNOLOGY CO., LTD, Shenzhen, Guangdong (CN)

(72) Inventor: Wen SHI, Shenzhen (CN)

(73) Assignee: SHENZHEN CHINA STAR OPTOELECTRONICS SEMICONDUCTOR DISPLAY TECHNOLOGY CO., LTD., Shenzhen, Guangdong (CN)

(21) Appl. No.: 15/736,393

(22) PCT Filed: Nov. 6, 2017
(86) PCT No.: PCT/CN2017/109512

§ 371 Date: Dec. 14, 2017

(30) Foreign Application Priority Data
Oct. 9, 2017 (CN) 201710929560.9

(51) Int. Cl. H01L 29/786; H01L 29/49; H01L 29/66; H01L 21/768; H01L 21/027

(52) U.S. Cl. CPC H01L 29/7869; H01L 29/4908; G02F 1/1368; H01L 21/76829; H01L 21/0274; H01L 29/66969

(57) ABSTRACT

A thin film transistor and a manufacturing method thereof are provided. The method includes sequentially forming a gate, a first sub-insulation layer on a substrate and a second sub-insulation layer on the gate, and a first sub-active layer on the first sub-insulation layer and a second sub-active layer on the second sub-insulation layer; coating and patterning a photoresist material layer to pattern the first and second sub-active layers to form an active layer pattern; removing a first photoresist layer of the photoresist material layer; using a second photoresist layer of the photoresist material layer as an etch stop structure; and forming a source and a drain respectively at both ends of the active layer pattern.

### FIELD OF THE INVENTION

The present disclosure relates to the field of manufacturing liquid crystal panels, and in particular to a thin film transistor and a method for manufacturing same.

### BACKGROUND OF DISCLOSURE

In the era of information society, importance of displays as visual media for information transmission is emphasized. In order to dominate future markets, display development is trending towards light weight, thin, low power consumption, low cost, and high image quality.

In recent years, with development of the panel display industry, demand for large-size and high-resolution panel displays has been increasing. As core technology of the panel display industry, thin film transistors (TFTs) have been developing significantly.

Metal oxide thin film transistors have drawn much attention due to high mobility, simple fabrication process, low manufacturing cost, and large area uniformity thereof. At present, structures mainly used in metal oxide TFTs include back channel etch (BCE) structures and the etch stop (ESL) structures. A metal oxide thin film transistor with an etch stop structure is relatively stable. However, this requires addition of an additional photomask process to manufacture an etch stop structure, resulting in a complicated process and high production costs.

Therefore, the prior art has defects and urgently needs to be improved.

### SUMMARY OF INVENTION

An object of the present disclosure is to provide an improved thin film transistor and a method for manufacturing the same.

In order to resolve the above problem, the technical solution provided in the present disclosure is as follows:

In an embodiment of the present disclosure, a method for manufacturing a thin film transistor is provided and includes steps of:

providing a substrate, and forming a gate on the substrate;

forming an insulation layer on the substrate, wherein the insulation layer includes a first sub-insulation layer on a surface of the substrate and a second sub-insulation layer on a surface of the gate;

forming an active layer on the insulation layer, wherein the active layer includes a first sub-active layer on a surface of the first sub-insulation layer and a second sub-active layer on a surface of the second sub-insulation layer;

coating a photoresist material layer on the active layer, patterning the photoresist material layer, and forming a first photoresist layer with a first thickness and a second photoresist layer with a second thickness on a surface of the second sub-active layer, wherein the first photoresist layer is disposed on both sides of the second photoresist layer, and the second thickness is greater than the first thickness;

etching the active layer to remove the first sub-active layer, and remaining the second sub-active layer as an active layer pattern;

removing the first photoresist layer to expose both ends of the active layer pattern, and remaining the second photoresist layer on a surface of the active layer pattern as an etch stop structure; and

forming a source and a drain respectively at both ends of the active layer pattern.

In an embodiment of the present disclosure, another method for manufacturing a thin film transistor is provided and includes steps of:

providing a substrate, and forming a gate on the substrate;

forming an insulation layer on the substrate, wherein the insulation layer includes a first sub-insulation layer on a surface of the substrate and a second sub-insulation layer on a surface of the gate;

forming an active layer on the insulation layer, wherein the active layer includes a first sub-active layer on a surface of the first sub-insulation layer and a second sub-active layer on a surface of the second sub-insulation layer;

coating a photoresist material layer on the active layer, performing an exposure on the photoresist material layer disposed on a surface of the first sub-active layer to remove the photoresist material layer on the surface of the first sub-active layer, performing a half-exposure on the photoresist material layer disposed at both ends of the second sub-active layer to form a first photoresist layer with a first thickness at the both ends of the second sub-active layer, and not performing any exposure on the remaining photoresist material layer disposed on the second sub-active layer to form a second photoresist layer with a second thickness on a surface of the second sub-active layer, wherein the first photoresist layer is disposed on both sides of the second photoresist layer, and the second thickness is greater than the first thickness;

etching the active layer to remove the first sub-active layer, and remaining the second sub-active layer as an active layer pattern;

ashing the first photoresist layer to remove the first photoresist layer to expose both ends of the active layer pattern, and remaining the second photoresist layer disposed on a surface of the active layer pattern as an etch stop structure; and

forming a source and a drain respectively at both ends of the active layer pattern.

Accordingly, in an embodiment of the present disclosure, a thin film transistor is also provided and includes:

a substrate;

a gate disposed on the substrate;

an insulation layer disposed on the substrate and the gate, wherein the insulation layer includes a first sub-insulation layer on a surface of the substrate and a second sub-insulation layer on a surface of the gate;

an active layer disposed on the second sub-insulation layer;

a photoresist layer disposed on an upper surface of the active layer and between both ends of the active layer, and exposing both ends of the active layer;

a source disposed at one end of the active layer and on the first sub-insulation layer; and

a drain disposed at other end of the active layer and on the first sub-insulation layer.

Compared with the conventional method for manufacturing a thin film transistor, the method for manufacturing the thin film transistor in accordance with the present disclosure includes steps of: providing a substrate, sequentially forming a gate and an insulation layer, wherein the insulation layer includes a first sub-insulation layer on a surface of the substrate and a second sub-insulation layer on a surface of the gate, forming an active layer on the insulation layer, wherein the active layer includes a first sub-active layer on a surface of the first sub-insulation layer and a second sub-active layer on a surface of the second sub-insulation layer, coating a photoresist material layer on the active layer, patterning the photoresist layer to form a first photoresist layer with a first thickness and a second photoresist layer with a second thickness on a surface of the second sub-active layer, wherein the first photoresist layer is disposed on both sides of the second photoresist layer, and the second thickness is greater than the first thickness, etching the active layer to remove the first sub-active layer, and remaining the second sub-active layer as an active layer pattern, removing the first photoresist layer to expose both ends of the active layer pattern, and remaining the second photoresist layer on a surface of the active layer pattern as an etch stop structure, and forming a source and a drain respectively at both ends of the active layer pattern. The photoresist mask for preparing the active layer is reused in this solution, and the remaining photoresist film is used as the etch stop structure for the source and the drain. It is not required to add an additional photomask process to manufacture the etch stop structure, thereby reducing the manufacturing cost.

### BRIEF DESCRIPTION OF DRAWINGS

FIG. 1 is a schematic flow chart of a method for manufacturing a thin film transistor in accordance with a preferred embodiment of the present disclosure.

FIG. 2 is a process schematic diagram corresponding to the method for manufacturing the thin film transistor, as shown in FIG. 1.

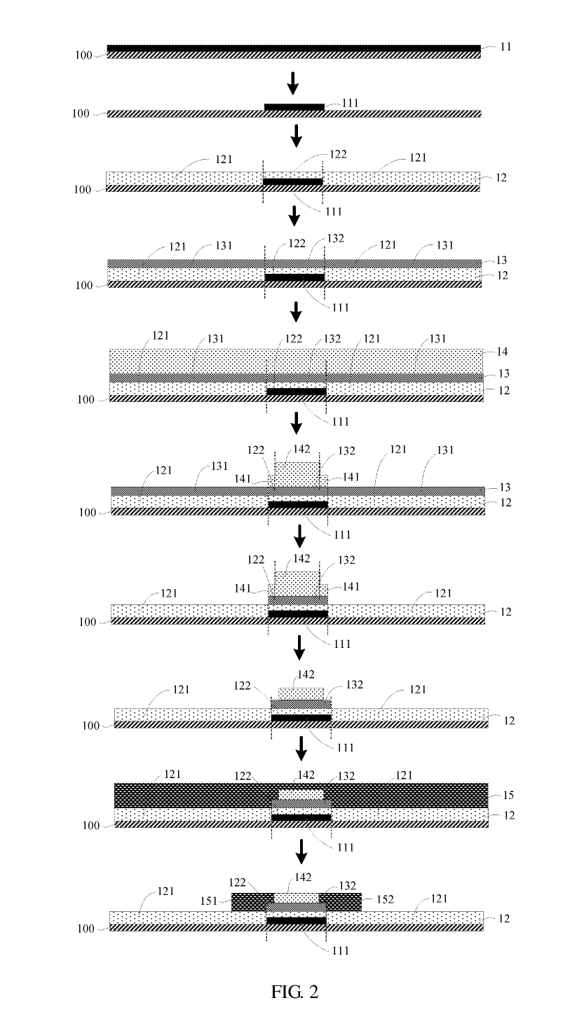

FIG. 3 is a schematic structural diagram of a thin film transistor in accordance with a preferred embodiment of the present disclosure.

### DETAILED DESCRIPTION OF PREFERRED EMBODIMENTS

The following description of the embodiments with reference to the accompanying drawings is used to illustrate particular embodiments of the present disclosure. The directional terms referred in the present disclosure, such as “upper”, “lower”, “front”, “back”, “left”, “right”, “inner”, “outer”, “side surface”, etc., are only directions with regard to the accompanying drawings. Therefore, the directional terms used for describing and illustrating the present disclosure are not intended to limit the present disclosure.

In the drawings, modules with similar structures are indicated by same reference number.

In addition, the terms “first” and “second” are used for descriptive purposes only, and are not to be construed as indicating or implying relative importance or implicitly indicating the number of the technical features. Thus, the features defined as “a first feature” and “a second feature” may explicitly or implicitly include one or more of the features. In the description of the present disclosure, “a plurality of” means two or more unless otherwise specified. In addition, the term “comprise” and any variations thereof are intended to cover a non-exclusive inclusion.

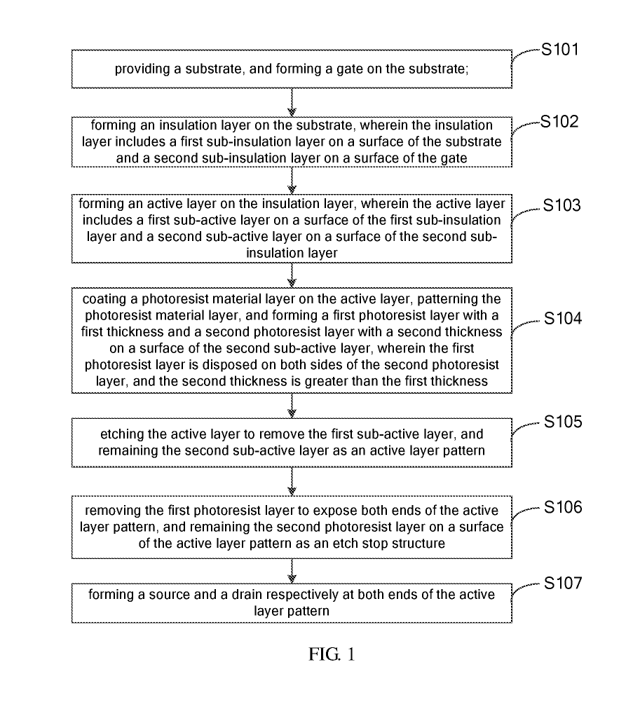

As shown in FIG. 1, a method for manufacturing a thin film transistor of the preferred embodiment includes the following steps:

In step S101, a substrate is provided, and a gate is formed on the substrate.

The substrate 100 may be a transparent rigid substrate or a flexible substrate. For example, the substrate 100 may be glass, quartz, a polyimide film (PI) layer, or the like.

In some embodiments, step S101 includes steps of depositing a metal layer 11 on the substrate, coating a photoresist with a uniform thickness, and forming a gate 111 on the substrate 100 by exposure and development of the photoresist and etching the metal layer exposing 11.

Specifically, the metal layer 11 may firstly be formed on the substrate 100, using a chemical vapor deposition (CVD) process. The metal layer 11 may be made of chromium (Cr), chromium alloy material, molybdenum tantalum (Mo and Ta) alloy material, aluminum, or aluminum (Al) alloy material. Subsequently, a photoresist with a uniform thickness is coated on the metal layer 11, the coated photoresist is exposed and developed by the yellow light process, and then the metal layer 11 not protected by the photoresist is etched by an etching process, thereby forming the gate 111 of the thin film transistor.

In step S102, an insulation layer is formed on the substrate, wherein the insulation layer includes a first sub-insulation layer on a surface of the substrate and a second sub-insulation layer on a surface of the gate.

Specifically, the insulating layer 12 may be deposited on the substrate 100 by a CVD method. The insulation layer 12 includes the first sub-insulation layer 121 on the surface of the substrate 100 and the second sub-insulation layer 122 on the surface of the gate electrode 111. The insulation layer 12 may be a one-layer structure or a two-layer structure. The first layer structure may be made of SiO, SiNx, or AlO. The second layer structure may generally be made of SiNx.

In step S103: an active layer is on the insulation layer, wherein the active layer includes a first sub-active layer on a surface of the first sub-insulation layer and a second sub-active layer on a surface of the second sub-insulation layer.

Specifically, the active layer 13 can be formed by depositing a semiconductor material over the entire surface of the insulation layer. The active layer 13 includes the first sub-active layer 131 on the surface of the first sub-insulation layer 121 and the second sub-active layer 132 on the surface of the second sub-insulation layer 122.

In some embodiments, the active layer 13 may be a semiconducting metal oxide film. Specifically, material of the metal oxide film can be indium gallium zinc oxide (IGZO).

In step S104, a photoresist material layer is coated on the active layer, the photoresist material layer is patterned, and a first photoresist layer with a first thickness and a second photoresist layer with a second thickness are formed on a surface of the second sub-active layer, wherein the first photoresist layer is disposed on both sides of the second photoresist layer, and the second thickness is greater than the first thickness.

Firstly, the entire photoresist material layer 14 is coated. The thickness of the photoresist material layer 14 is much greater than the thickness of the active layer 13. Then, the photoresist material layer 14 is patterned to form the first photoresist layer 141 with the first thickness and the second photoresist layer 142 with the second thickness on the surface of the second sub-active layer 132. The first photoresist layer 141 is distributed on the both sides of the second photoresist layer 142, and the second thickness is greater than the first thickness. The photoresist material layer 14 can be a photoresist.

In some embodiments, the photoresist layer 14 may be patterned by a half-exposure process, such as using a half tone mask or a gray tone mask to expose the photoresist layer 14. That is, the step of patterning the photoresist layer 14 includes steps of:

performing a full exposure on the photoresist material layer disposed on a surface of the first sub-active layer 131 to remove the photoresist material layer on the surface of the first sub-active layer 131; performing a half-exposure on the photoresist material layer disposed at the both ends (end A and end B) of the second sub-active layer 132 to form the first photoresist layer with the first thickness at the both ends (end A and end B) of the second sub-active layer 132; and not performing any exposure on the remaining photoresist material layer disposed on the second sub-active layer 132 to form the second photoresist layer 142 with the second thickness on a surface of the second sub-active layer. Thereby a stepped photoresist pattern is formed on the active layer 13.

In step S105, the active layer is etched to remove the first sub-active layer, and the second sub-active layer remains as an active layer pattern.

Specifically, the entire substrate may be etched through a wet etching process to remove the first sub-active layer 131, and the remaining second sub-active layer 132 is used as an active layer pattern.

In step S106, the first photoresist layer is removed to expose both ends of the active layer pattern, and the second photoresist layer remains on a surface of the active layer pattern as an etch stop structure.

The first photoresist layer 141 is removed to expose the both ends (end A and end B) of the active layer pattern (i.e., the second sub-active layer 132), and the second photoresist layer 142 serves as the etch stop structure. In the embodiments of the present disclosure, there are many ways to remove the first photoresist layer 131.

For example, the first photoresist layer may be ashed to remove the first photoresist layer 141, to expose the both ends of the active layer pattern (i.e., the both ends of the second sub-active layer 132). In this process, the thickness of the second photoresist layer 142 also becomes thinner accordingly. In a specific embodiment, the photoresist layer pattern may be ashed by providing O₂ at a high temperature to reduce the overall thickness of the photoresist layer pattern, thereby completely reacting and removing the first photoresist layer 141.

In step S107: a source and a drain at both ends of the active layer pattern are formed.

Specifically, the metal layer 15 may be deposited over the surface, to cover the first sub-insulation layer 121, the exposed both ends (i.e., end A and end B) of the active layer pattern (i.e., the second sub-active layer 132), and the etch stop structure (i.e., the thinned second photoresist layer 142).

In some embodiments, the metal layer 15 may be patterned to remove the metal layer located on the etch stop structure (i.e., the thinned second photoresist layer 142), to form the source 151 and the drain 152 disposed at an interval respectively at the both ends of the active layer pattern (i.e., the second sub-active layer 132).

The metal layer 15 can be made of chromium (Cr), chromium alloy material, molybdenum tantalum (Mo Ta) alloy material, aluminum (Al) or aluminum alloy material.

From the above, in the method for manufacturing the thin film transistor provided by the embodiment of the present disclosure, when the photoresist mask on the active layer is formed, the fully-remaining region of the photoresist film is formed in a channel region of the active layer of the TFT, the semi-remaining region of the photoresist film is formed in the region of the active layer contacting the source and the drain, and no photoresist film is provided in other regions. Afterwards, the active layer is etched to form the active layer pattern, and then the photoresist mask is directly patterned to remove the photoresist in the semi-remaining region. Simultaneously, a photoresist film remains in the channel region of the active layer, and the photoresist film serves as the etch stop structure for the source and drain. The photoresist mask for preparing the active layer is reused in this solution, and the remaining photoresist film is used as the etch stop structure for the source and the drain. It is not required to add an additional photomask process to manufacture the etch stop structure, thereby reducing the manufacturing cost.

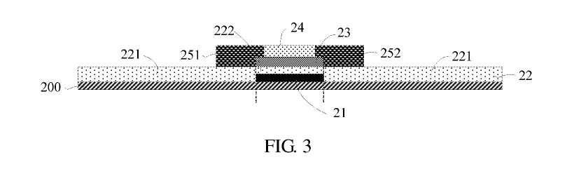

An embodiment of the present disclosure further provides a thin film transistor, which may be fabricated by any method for manufacturing the thin film transistors in the above embodiments. Refer to FIG. 3, which is a schematic structural diagram of a thin film transistor in accordance with a preferred embodiment of the present disclosure. As shown in FIG. 3, the thin film transistor in the preferred embodiment includes:

a substrate 200;

a gate 21 disposed on the substrate,

an insulation layer 22 disposed on the substrate 200 and the gate 21, wherein the insulation layer 22 includes a first sub-insulation layer 221 on a surface of the substrate 200 and a second sub-insulation layer 222 on a surface of the gate 21;

an active layer 23 disposed on the second sub-insulation layer 222;

a photoresist layer 24 disposed on an upper surface of the active layer 23 and between both ends of the active layer 23, and exposing both ends of the active layer;

a source 251 disposed at one end of the active layer 23 and on the first sub-insulation layer 21; and

a drain 252 disposed at other end of the active layer 23 and on the first sub-insulation layer 21.

The substrate 200 may be a transparent rigid substrate or a flexible substrate. For example, the substrate 200 may be glass, quartz, PI, or the like.

In some embodiments, the gate 21 may be formed by coating a metal layer on the substrate 200, coating a photoresist with a uniform thickness, exposing and developing the photoresist, and etching the metal layer. The metal layer may be made of chromium (Cr), chromium alloy material, molybdenum tantalum (Mo Ta) alloy material, aluminum (Al) or aluminum alloy material. When depositing the metal layer, the metal layer may be deposited by a CVD process.

In some embodiments, the insulation layer 22 may be a one-layer structure or a two-layer structure. The first layer structure may be made of SiO, SiNx, or AlO. The second layer structure may generally be made of SiNx.

In some embodiments, the active layer 13 may be a semiconducting metal oxide film. Specifically, material of the metal oxide film can be indium gallium zinc oxide (IGZO).

In the embodiment of the present disclosure, the photoresist layer 24 can be made of a photoresist mask for preparing the active layer 23. Specifically, after the active material layer is deposited on the substrate 200, the photoresist material layer is deposited on the entire active layer, wherein the thickness of the photoresist layer is much greater than the thickness of the active material layer. The photoresist material layer is patterned by a half-exposure process. That is, a full exposure is performed on the photoresist material layer disposed on a surface of the first sub-active layer 221, a half-exposure is performed on the photoresist material layer disposed at the both ends of the second sub-active layer 222, and no exposure is performed on the photoresist material layer on the active material layer between the both ends of the second sub-active layer 222. Thereby a stepped photoresist material pattern is formed on the active layer. The active material layer is etched, using the patterned photoresist as a mask, to form a patterned active material layer (i.e., the active layer 23). The photoresist layer 24 may be obtained by patterning a stepped photoresist material pattern through a plasma stripping process, to remove the photoresist material with the first thickness, and expose the upper surfaces of the both ends of the active layer 23. The photoresist layer 24 serves as an etch stop structure (ESL) of the thin film transistor. In the process of forming the source 251 and the drain 252, the active layer 23 can avoid oxidation to ensure the characteristics thereof.

The source 251 and the drain 252 may be made of chromium (Cr), chromium alloy material, molybdenum tantalum (Mo Ta) alloy material, aluminum (Al) or aluminum alloy material.

The photoresist mask for preparing the active layer is reused in this solution, and the remaining photoresist film is used as the etch stop structure for the source and the drain. It is not required to add an additional photomask process to manufacture the etch stop structure, thereby reducing the manufacturing cost.

In summary, although the preferable embodiments of the present disclosure have been disclosed above, the embodiments are not intended to limit the present disclosure. A person of ordinary skill in the art, without departing from the spirit and scope of the present disclosure, can make various modifications and variations. Therefore, the scope of the disclosure is defined in the claims.

What is claimed is:

1. A method for manufacturing a thin film transistor, comprising steps of:
providing a substrate, and forming a gate on the substrate;
forming an insulation layer on the substrate, wherein the insulation layer includes a first sub-insulation layer on a surface of the substrate and a second sub-insulation layer on a surface of the gate;
forming an active layer on the insulation layer, wherein the active layer includes a first sub-active layer on a surface of the first sub-insulation layer and a second sub-active layer on a surface of the second sub-insulation layer;
coating a photoresist material layer on the active layer, patterning the photoresist material layer, and forming a first photoresist layer with a first thickness and a second photoresist layer with a second thickness on a surface of the second sub-active layer, wherein the first photoresist layer is disposed on both sides of the second photoresist layer, and the second thickness is greater than the first thickness;
etching the active layer to remove the first sub-active layer, and using a remaining portion of the second sub-active layer as an active layer pattern;
removing the first photoresist layer to expose both ends of the active layer pattern, and remaining the second photoresist layer on a surface of the active layer pattern as an etch stop structure; and
forming a source and a drain at both ends, respectively, of the active layer pattern.

2. The method for manufacturing the thin film transistor as claimed in claim 1, wherein the step of patterning the photoresist material layer, and forming the first photoresist layer with the first thickness and the second photoresist layer with the second thickness on the surface of the second sub-active layer comprises steps of:
performing an exposure on the photoresist material layer disposed on a surface of the first sub-active layer to remove the photoresist material layer on the surface of the first sub-active layer;
performing a half-exposure on the photoresist material layer disposed at both ends of the second sub-active layer to form the first photoresist layer with the first thickness at the both ends of the second sub-active layer; and
not performing any exposure on a remaining portion of the photoresist material layer disposed on the second sub-active layer to form the second photoresist layer with the second thickness on a surface of the second sub-active layer.

3. The method for manufacturing the thin film transistor as claimed in claim 2, wherein the step of performing the exposure on the photoresist layer uses a half-tone mask.

4. The method for manufacturing the thin film transistor as claimed in claim 2, wherein the step of performing the exposure on the photoresist material layer uses a grayscale mask.

5. The method for manufacturing the thin film transistor as claimed in claim 1, wherein the step of removing the first photoresist layer to expose the both ends of the active layer pattern comprises a step of:
ashing the first photoresist layer to remove the first photoresist layer to expose the both ends of the active layer pattern.

6. The method for manufacturing the thin film transistor as claimed in claim 1, wherein the step of forming the source and the drain respectively at the both ends of the active layer pattern comprises steps of:
depositing a first metal layer to cover the first sub-insulation layer, the exposed both ends of the active layer pattern and the etch stop structure; and
patterning the first metal layer to remove the first metal layer disposed on the etch stop structure to form the source and the drain at the both ends of the active layer pattern.

7. The method for manufacturing the thin film transistor as claimed in claim 1, wherein the active layer is a metal oxide film with a semiconducting property.

8. The method for manufacturing the thin film transistor as claimed in claim 7, wherein the metal oxide film is indium gallium zinc oxide.

9. The method for manufacturing the thin film transistor as claimed in claim 1, wherein the step of forming the gate on the substrate comprises steps of:
depositing a second metal layer on the substrate and coating a photoresist with an uniform thickness; and
forming the gate on the substrate by exposure and development of the photoresist and etching the second metal layer.

10. The method for manufacturing the thin film transistor as claimed in claim 1, wherein the substrate is a transparent glass.

11. A method for manufacturing a thin film transistor, comprising steps of:
providing a substrate, and forming a gate on the substrate;
forming an insulation layer on the substrate, wherein the insulation layer includes a first sub-insulation layer on a surface of the substrate and a second sub-insulation layer on a surface of the gate;
forming an active layer on the insulation layer, wherein the active layer includes a first sub-active layer on a surface of the first sub-insulation layer and a second sub-active layer on a surface of the second sub-insulation layer;
coating a photoresist material layer on the active layer, performing an exposure on the photoresist material layer disposed on a surface of the first sub-active layer to remove the photoresist material layer on the surface of the first sub-active layer, performing a half-exposure on the photoresist material layer disposed at both ends of the second sub-active layer to form a first photoresist layer with a first thickness at the both ends of the second sub-active layer, and not performing any exposure on the remaining photoresist material layer disposed on the second sub-active layer to form a second photoresist layer with a second thickness on a surface of the second sub-active layer, wherein the first photoresist layer is disposed on both sides of the second photoresist layer, and the second thickness is greater than the first thickness;
etching the active layer to remove the first sub-active layer, and remaining the second sub-active layer as an active layer pattern;
ashing the first photoresist layer to remove the first photoresist layer to expose both ends of the active layer pattern, and remaining the second photoresist layer disposed on a surface of the active layer pattern as an etch stop structure; and
forming a source and a drain respectively at both ends of the active layer pattern.

12. The method for manufacturing the thin film transistor as claimed in claim 11, wherein the step of performing the exposure on the photoresist material layer uses a half-tone mask or a grayscale mask.

13. The method for manufacturing the thin film transistor as claimed in claim 12, wherein the step of forming the source and the drain respectively at the both ends of the active layer pattern comprises steps of:
depositing a first metal layer to cover the first sub-insulation layer, the exposed both ends of the active layer pattern and the etch stop structure; and
patterning the first metal layer to remove the first metal layer disposed on the etch stop structure to form the source and the drain at the both ends of the active layer pattern.

14. The method for manufacturing the thin film transistor as claimed in claim 13, wherein the active layer is a metal oxide film with a semiconducting property.

15. The method for manufacturing the thin film transistor as claimed in claim 14, wherein the metal oxide film is indium gallium zinc oxide.

16. The method for manufacturing the thin film transistor as claimed in claim 11, wherein the step of forming the source and the drain respectively at the both ends of the active layer pattern comprises steps of:
depositing a first metal layer to cover the first sub-insulation layer, the exposed both ends of the active layer pattern and the etch stop structure; and
patterning the first metal layer to remove the first metal layer disposed on the etch stop structure to form the source and the drain at the both ends of the active layer pattern.

17. The method for manufacturing the thin film transistor as claimed in claim 11, wherein the substrate is a transparent glass.

18. A thin film transistor, comprising:
a substrate;
a gate disposed on the substrate;
an insulation layer disposed on the substrate and the gate, wherein the insulation layer includes a first sub-insulation layer on a surface of the substrate and a second sub-insulation layer on a surface of the gate;
an active layer disposed on the second sub-insulation layer;
a photoresist layer disposed on an upper surface of the active layer and between both ends of the active layer, and exposing both ends of the active layer;
a source disposed at one end of the active layer and on the first sub-insulation layer; and
a drain disposed at other end of the active layer and on the first sub-insulation layer.

19. The thin film transistor as claimed in claim 18, wherein material of the active layer is indium gallium zinc oxide.

20. The thin film transistor as claimed in claim 18, wherein material of the insulating layer is silicon oxide and/or silicon nitride.
